(19) United States
(12) Patent Application Publication
(10) Pub. No.: US 2010/0213472 A1
(43) Pub. Date: Aug. 26, 2010

(54) Photo-gating Switch System

(75) Inventors: Sun-Jin Yun, Daejeon-City (KR); Yong-Wook Lee, Daejeon-City (KR); Hyn Tak Kim, Daejeon-City (KR); Bong-Jun Kim, Daejeon-City (KR); JungWook LIM, Daejeon-City (KR); Sung-Youl Choi, Ulsan-City (KR)

Correspondence Address: RABIN & Berdo, PC, 1101 14TH STREET, NW, SUITE 500, WASHINGTON, DC, 20005, US

(73) Assignee: Electronics and Telecommunications Research Institute, Daejeon-City (KR)

(21) Appl. No.: 12/681,615

(22) PCT Filed: Oct. 6, 2008
(86) PCT No.: PCT/KR08/05845

§ 371 Date: Apr. 2, 2010

(30) Foreign Application Priority Data
Oct. 5, 2007 (KR) 10-2007-0100602

(51) Int. Cl. H01L 31/12

(52) U.S. Cl. 257/84; 257/E33.077

(57) ABSTRACT

A photo-gating switch system comprising a photosensitive device formed on a substrate is provided. The photosensitive device may comprise a photosensitive layer and electrodes formed at both ends of the photosensitive layer. A light source irradiating light to the photosensitive device is integrated beneath the surface of the substrate.

### TECHNICAL FIELD

The present invention relates to a photo-gating switch system.

### BACKGROUND ART

Photo switches are photonic devices that perform on/off switching in response to light. Photo switches may be used in various fields, for example, in image processors or image readers such as facsimile or digital copier apparatuses, as well as a simple on/off switch.

An actual usage of a photo switch is disclosed in U.S. Pat. No. 5,354,981 entitled ‘Switching Photosensitive Matrix Device.’ This U.S. patent describes a photo switch array for an image sensor, wherein a PNPN thyristor that generates output signals in response to pulsed light is used as the photo switch.

Since fast on/off switching in response to light and excellent photosensitivity are essential for photo switches, development of a photo switch having such characteristics is very important.

### DISCLOSURE OF INVENTION

### Technical Solution

The present invention provides a photo-gating switch system with fast on/off switching and excellent photosensitivity.

The present invention also provides a photo-gating switch system in which a light source and a photosensitive device such as photo-detector or photo-switches may be easily integrated.

According to an aspect of the present invention, there is provided a photo-gating switch system including a photosensitive device formed on a substrate. The photosensitive device may include a photosensitive layer formed on the substrate and electrodes formed at both ends of the photosensitive layer. In the photo-gating switch system according to an embodiment of the present invention, a light source irradiating light to the photosensitive device is integrated beneath the substrate on which the photo sensitive device is formed.

The photosensitive device includes a photo sensitive layer having a photosensitive region, to which light is irradiated from the light source, and the substrate may be thinned in the photosensitive region by selectively forming a groove from the rear surface of the substrate. The groove may be formed to expose the photosensitive layer of the photosensitive region toward the light source. By forming the grooves, the efficiency of the photosensitive devices is enhanced due to the decrease of light loss caused by the light absorption or reflection by substrate. The use of grooves is beneficial for both transparent and opaque substrates. The photosensitive device may be a metal-insulator transition (MIT) device on which an MIT occurs when light (electromagnetic waves) or both light and an electric field are applied to the device.

According to another aspect of the present invention, there is provided a photo-gating switch system including a photosensitive device array in which a plurality of unitary photosensitive devices are formed in an array shape on a substrate. The unitary photosensitive device may include a photosensitive layer formed on a substrate and electrodes formed at both ends of the photosensitive layer. In the photo-gating switch system according to an embodiment of the present invention, a light source is located beneath the photosensitive device array including the substrate on which the unitary photosensitive devices are formed. The light source may be integrated as a light source array module in which unitary light sources irradiating light are formed in correspondence to the unitary photosensitive devices. The light source may also be embodied using a distributor so that light may reach the photosensitive device array with uniform intensity.

The unitary photosensitive devices may include the photosensitive layer, which has a photosensitive region to which light is irradiated from the unitary light source, and a groove may be formed in a rear surface of the substrate corresponding to the photosensitive region by locally thinning the substrate in the photosensitive region, or the groove may be formed to expose the photosensitive region of the photosensitive film. Partition walls sectioning the unitary light sources may be introduced between the unitary light sources and on the light source array modules at both ends of the groove. The unitary photosensitive device may be an MIT device in which the MIT occurs when light (electromagnetic waves), or both light and an electric field are applied. The unitary photosensitive device may be a device showing nonlinear current behavior (for example, nonlinear current jump, etc.) by irradiating light while an electric field is applied.

According to another aspect of the present invention, there is provided a photo-gating switch system including a photosensitive device array in which a plurality of photosensitive devices are formed in an array shape on a substrate. Also, the photo-gating switch system according to an embodiment of the present invention may include a singular light source, located beneath the photosensitive device array including the substrate on which the unitary photosensitive devices are formed, irradiating light from behind of the unitary photosensitive devices. The singular light source may use a distributor so that light may reach the photosensitive device array with laterally uniform intensity.

Since the photo-gating switch system of the present invention may use the MIT device as the photosensitive device, the photo-gating switch system has the advantages of fast on/off switching and excellent photosensitivity.

The photosensitive device and the light source are separately formed in the photo-gating switch system according to an embodiment of the present invention. Therefore, the photo-gating switch system according to an embodiment of the present invention may be manufactured with high yield by fabricating the light source independently of photosensitive device fabrication, and the photosensitive device and the light source may be isolated to address negative effects due to residual gas generated by deterioration of the photosensitive device or the light source.

In a photo-gating switch system according to the present invention, the light source may be integrated by using the photosensitive device as a cover glass, instead of using a separate cover glass or passivating films.

A photo-gating switch system according to the present invention includes the photosensitive device having the substrate on which the groove is formed. That is, the photo-gating switch system may be able to increase photo-transmittance and focus light to the photosensitive region via the groove. Also, when the photo-gating switch system of the present invention includes a non-transmissive substrate, the photosensitive film can be exposed to light irradiated from backside by making the substrate thickness of the groove region zero or thin enough to transmit the light through.

### ADVANTAGEOUS EFFECTS

A photo-gating switch system includes a photosensitive device sensitive to light (electromagnetic waves) and a light source. The photosensitive device includes photosensitive layers having various structures or shapes. When light is irradiated to the photosensitive layers, the photosensitive layers sense the light. An example of the photosensitive layer is a metal-insulator transition (MIT) layer. The MIT layer is a layer on which a MIT occurs when an impulse is applied to the layer. If the MIT layer is used as the photosensitive layer, the photosensitive device may utilize MIT characteristics.

The MIT occurs when an impulse such as an electric field (an electric current), heat, light, or pressure is applied to the MIT layer with an intensity exceeding a critical value. MIT may occur on any known material if certain conditions are met. The critical value of the impulse at which MIT can occur varies according to the material of the MIT layers.

Therefore, the photosensitive device may include any material on which MIT may occur. Representatively, the MIT layer may be a semiconductor material such as II-VI compounds and III-V compounds known as the compound semiconductors, or an insulating material such as an oxide. The unitary photosensitive device may be a device showing nonlinear current behavior (for example, nonlinear current jump, etc.) by irradiating light while an electric field is applied.

### BRIEF DESCRIPTION OF THE DRAWINGS

The above and other features and advantages of the present invention will become more apparent by describing in detail exemplary embodiments thereof with reference to the attached drawings in which:

FIGS. 1 through 3 are sectional views of a metal-insulator transition (MIT) device used as an example of the photosensitive device of the present invention;

FIGS. 4 and 5 are graphs of current-voltage characteristics of two different kinds of the MIT devices shown in FIGS. 1 through 3, obtained before and after light is irradiated to the MIT device;

FIGS. 6, 7a and 7b are sectional views showing the concept of a photo-gating switch system according to an embodiment of the present invention;

FIGS. 8 and 9 are plan views of embodiments of grooves formed in a rear surface of a substrate at which the photosensitive device shown in FIG. 7 is formed;

FIG. 10 is a plan view of a light source array which can be used in the an array-shaped photo-gating switch system according to an embodiment of the present invention;

FIGS. 11 and 12 are sectional views of an array-shaped photo-gating switch system according to another embodiment of the present invention;

FIG. 13 is a plan view of a photosensitive device array shown in FIGS. 11 and 12;

FIGS. 14 and 15 are sectional views of an array-shaped photo-gating switch system in which the photosensitive device array and a light source array module are integrated according to another embodiment of the present invention;

FIGS. 16 and 17 are sectional views of the array-shaped photo-gating switch system comprising partition walls according to an embodiment of the present invention; and

FIG. 18 is a view of a photo-gating switch system in which a single and uniform light source may turn on/off the array-shaped photosensitive devices simultaneously according to another embodiment of the present invention.

### MODE FOR THE INVENTION

The present invention will now be described more fully with reference to the accompanying drawings, in which exemplary embodiments of the invention are shown. The invention may, however, be embodied in many different forms and should not be construed as being limited to the embodiments set forth herein; rather, these embodiments are provided so that this disclosure will be thorough and complete, and will fully convey the concept of the invention to those skilled in the art. In the drawings, the thicknesses of layers and regions are exaggerated for clarity. Like reference numerals in the drawings denote like devices.

A photo-gating switch system according to the present invention includes a photosensitive device sensitive to light (electromagnetic waves) and a light source. The photosensitive device includes photosensitive layers having various structures or shapes. When light is irradiated to the photosensitive layers, the photosensitive layers sense the light. An example of the photosensitive layer is a metal-insulator transition (MIT) layer. The MIT layer is a layer on which a MIT occurs when an impulse is applied to the layer. If the MIT layer is used as the photosensitive layer, the photosensitive device may utilize MIT characteristics.

MIT and the photosensitive device using the MIT will be described in closer details. The MIT occurs when an impulse such as an electric field (an electric current), heat, light, or pressure is applied to the MIT layer with an intensity exceeding a critical value. MIT may occur on any known material if certain conditions are met. The critical value of the impulse at which MIT can occur varies according to the material of the MIT layers.

Therefore, the photosensitive device may include any material on which MIT may occur. Representatively, the MIT layer may be a semiconductor material such as II-VI compounds and III-V compounds known as the compound semiconductors, or an insulating material such as an oxide. Although the MIT device described hereinafter is a two-terminal device, it is possible for those skilled in the art to modify the MIT device to a three-terminal device or a device with other structure. The unitary photosensitive device may be a device showing nonlinear current behavior (for example, nonlinear current jump, etc.) by irradiating light while an electric field is applied. The photosensitive devices include II-VI compound semiconductor devices and III-V compound semiconductor or oxide devices including GaAs, InP, ZnS, ZnSe, and ZnO, etc.

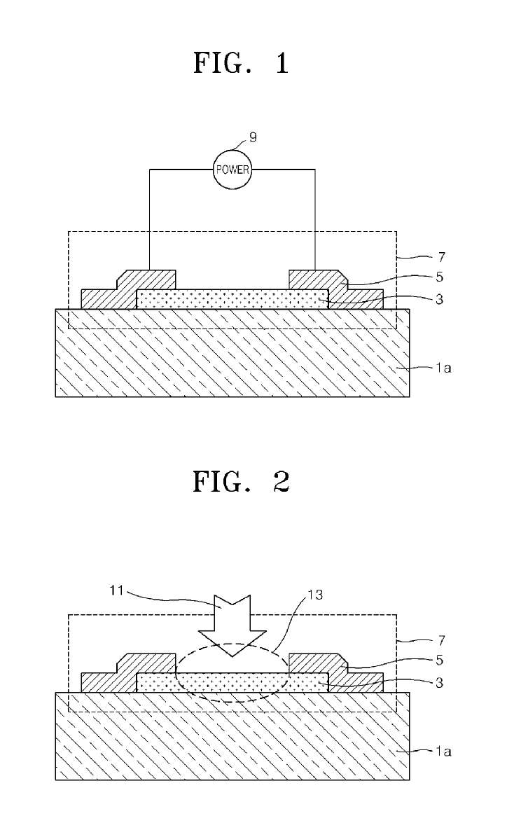

FIGS. 1 through 3 are sectional views of an MIT device used as an example of the photosensitive device of the present invention.

More particularly, in an MIT device 7, an MIT layer 3 is formed as a photosensitive layer on a non-transparent substrate 1, and electrodes 5 are formed at both ends of the MIT layer 3. However, as shown in FIG. 1, if an electric field, which is either an electric voltage or an electric current, exceeding a certain intensity is applied to the MIT layer 3 by a power supply 9, MIT occurs at MIT layer 3 connected to the two electrodes 5. Thus, the MIT device 7 may control a current whether to flow or not to flow between the two electrodes 5. In other words, the MIT device 7 may perform switching.

MIT occurs on the MIT device 7 if light 11 is irradiated to the MIT layer 3 between the two electrodes 5, that is, to a photosensitive region 13 as shown in FIG. 2. Thus, the MIT device 7 may control a current whether to flow or not to flow by either irradiating or screening light between the two electrodes 5. FIG. 3 is a combination of FIGS. 1 and 2, and MIT occurs easily by applying an electric field to the MIT layer 3 by the power supply 9 simultaneously with irradiating the light 11 to the MIT layer 3 as shown in FIG. 3. Thus, the MIT device 7 may switch a current so as to flow or not to flow between the two electrodes 5.

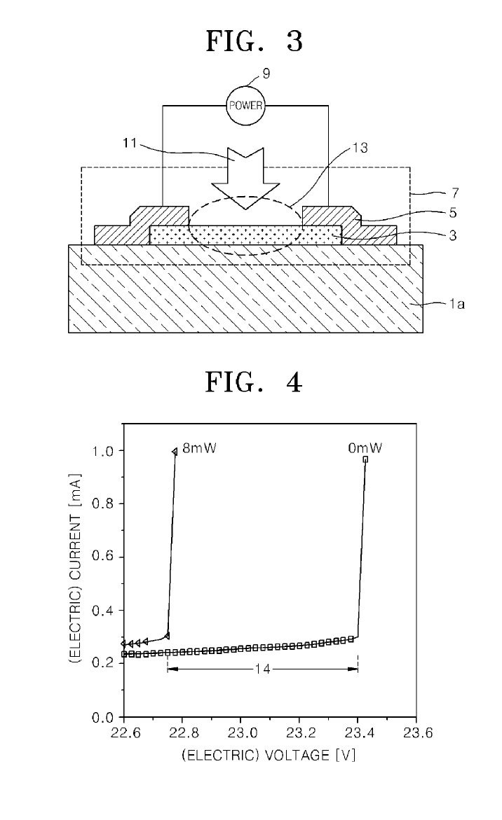

FIGS. 4 and 5 are graphs of current-voltage characteristics of the photosensitive device, which is a MIT device, shown in FIG. 3, obtained before and after light is irradiated to the MIT device.

More particularly, FIGS. 4 and 5 are graphs of current-voltage characteristics obtained by irradiating infrared light to the MIT layer 3, when MIT layer 3 is a vanadium-dioxide layer and a p-type GaAs layer, respectively. As shown in FIGS. 4 and 5, the electric current increases dramatically when an electric field is applied to the MIT layers 3, that is, the MIT occurs. However, the MIT voltage at which the MIT occurs is a relatively low voltage in FIG. 4 when infrared light is irradiated to the MIT layer 3, while the MIT voltage at which the MIT occurs is a relatively high voltage in FIG. 5 when infrared light is irradiated to the MIT layer 3. Thus, the change of the MIT voltage either increases or decreases linearly proportional to the intensity of light.

The photo switching operation of the MIT device 7 shown in FIG. 3 will be described hereinafter with reference to FIGS. 4 and 5.

More particularly, in FIG. 4, if 8 mW of light is irradiated to the MIT device 7 while a voltage within an on/off switching voltage region 14 is applied, the MIT device 7 is switched from off to on. The intensity of light to turn on the MIT device 7 is decided by the voltage applied to the device, and the voltage at which the MIT device 7 is turned on may decrease significantly if the intensity of light increases. The MIT device 7 including the vanadium-dioxide layer shows a linear decrease of the voltage at which the MIT device 7 is turned on as the intensity of light increases.

In FIG. 5 however, if a voltage within the on/off switching voltage region 14 is applied to the MIT device 7, the MIT device 7 is turned on when light is not irradiated, that is, 0 μW of light is irradiated to the MIT device 7. If 0.88 μW of light is irradiated, the MIT device 7 is turned off. And, the voltage at which the MIT device 7 is turned on may increase further if the intensity of light increases. The MIT device 7 including a p-type GaAs layer shows a linear increase of the voltage at which the MIT device 7 is turned on as the intensity of light increases. Such characteristics may enable reversal of switching characteristics if a circuit(s) is added further to the MIT device 7.

As shown in FIGS. 4 and 5, photo switching (gating) is performed smoothly by using the MIT device 7. Especially in FIG. 5, the photosensitive device with higher sensitivity may be used since the change of the MIT voltage according to the change of the intensity of light is much greater. As shown in FIGS. 4 and 5, depending on a material of the MIT layer 3, the photosensitivity may vary dramatically and even an on/off reversing may be possible.

While the stability of the MIT device 7 may be decreased as the intensity of the current flowing increases after the MIT occurs, the MIT device 7 may become stable by limiting the intensity of the current flowing through the photosensitive device. Also, since the MIT voltage is changed by the size of the MIT device 7 and the intensity of light, voltages with various intensities may be applied to the MIT device 7 according to a purpose of the use of the photosensitive device, and the intensity of light required for turning on/off the MIT device 7 can be varied as well.

As described hereinbefore, on/off light switching may be controlled using the MIT layer, that is, the photosensitive layer. Hereinafter, a photo-gating switch system including the MIT device as a photosensitive device will be described. As described hereinbefore, the photosensitive layer may be composed of various photosensitive material if the MIT layer is not used as the photosensitive layer.

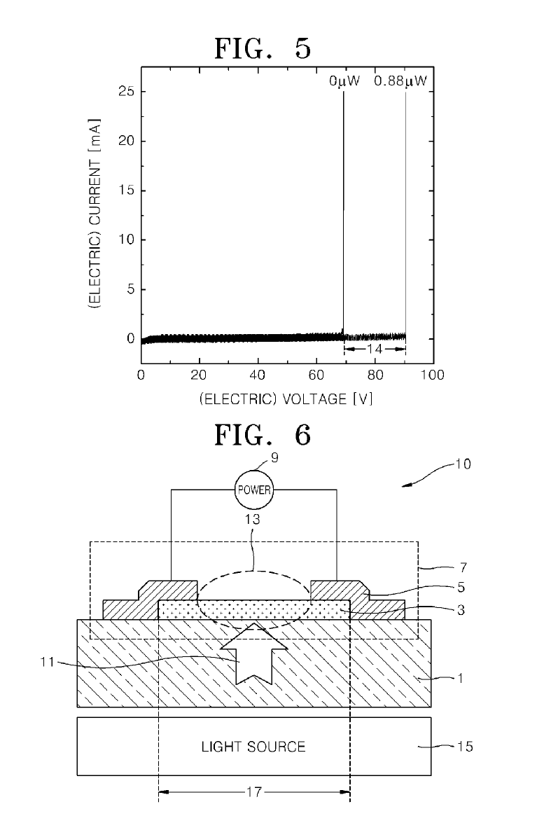

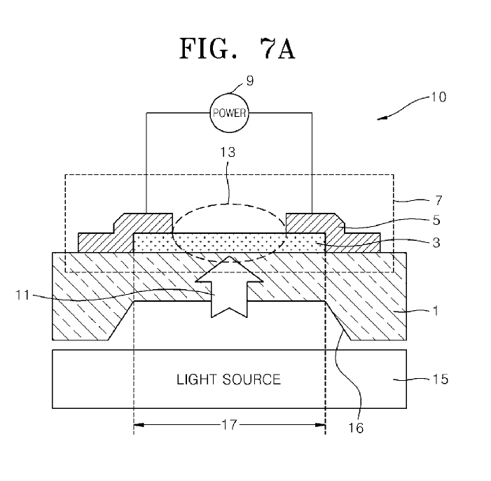

FIGS. 6 7, 7a and 7b are sectional views illustrating the most simplified concept of the photo-gating switch system according to the present embodiment, and FIGS. 8 and 9 are plan views of embodiments of the shape of a groove formed in the rear surface of the photosensitive device substrate shown in FIGS. 7a and 7b. In FIGS. 8 and 9, the shape of the groove may vary in consideration of factors such as patterning convenience, patterning costs, etc.

More particularly, FIGS. 6, 7a and 7b show photo-gating switch systems 10 configured so that light (electromagnetic waves), goes through a substrate 1 to reach a photosensitive region 13. Especially, a photosensitive device 7 shown in FIG. 6 is formed on the transparent substrate 1. A photosensitive device 7 shown in FIG. 7a is formed on the transparent substrate 1 in which the groove 16 is formed selectively from the rear surface of the substrate 1. A photosensitive device 7 shown in FIG. 7b is formed on the nontransparent substrate 1 in which the groove 16 exposing the rear surface of the substrate 1 and is formed selectively from the rear surface of the substrate. If the substrate 1 is thinner in a photo-transmissive region 17 where the groove 16 is formed, the light may be used more efficiently. Therefore, the substrate 1 in the photo-transmissive region 17 may be completely removed to expose the rear of an MIT layer 3 as the photosensitive layer.

More particularly, the MIT device 7 as shown in FIG. 3 is formed as a photosensitive device on the substrate 1, which is, for example, a photo-transparent substrate in the photo gating switch system 10 according to the present embodiment. The MIT occurs on the MIT device 7 if light or both light and an electric field are applied as described hereinbefore.

Also, a photo-gating switch system 10 shown in FIGS. 6, 7a and 7b includes a light source 15, for irradiating light to the MIT device 7, beneath the substrate 1 on which the MIT device 7 is formed.

The substrate 1 may have any thickness as long as it transmits light from the light source 15, but the substrate 1 may be further thinned in the area corresponding to the groove 16 in order to obtain higher photosensitivity. Elements such as silicon, glass, quartz, sapphire, or a polymer plastic transparent substrate may be used to form the substrate 1.

The MIT device 7 shown in FIGS. 6 and 7 includes the MIT layer 3 formed on the transparent substrate 1, and the electrodes 5 formed at both ends of the MIT layer 3. Any photosensitive layer may be used if the MIT layer 3 is not formed as the photosensitive layer.

As shown in FIG. 6, FIGS. 7a, and 7b, when the light 11 is irradiated from the rear side of the substrate, the area of the region irradiated by light 11 is larger than that of the region irradiated from front side because the electrodes normally reflect the light 11. Therefore, the structure of the present invention provides a high photosensitivity compared to a conventional structure.

In the photo-gating switch system 10 according to an embodiment of the present invention, the light 11 is irradiated from the light source 15 beneath the substrate 1 to the photosensitive region 13 of the MIT layer 3 through the transparent region 17. The substrate 1 may be any transparent substrate. For example, the substrate 1 may be a glass substrate transmitting a wide range of wavelengths including visible, infrared, and near-ultraviolet rays. The substrate may be one of a sapphire, quartz, plastics, and flexible polymer films.

The thickness of the transparent substrate may be between 0.1 mm and 1.0 mm. The flexible substrate may be thinner than 0.5 mm and thicker than 0.01 mm according to a specific application. However, if the thickness of the substrate is too thick in comparison to the area of the photosensitive region 13, light may be scattered and may be partially reflected, so that the intensity of light on the photosensitive region may be weakened, thereby decreasing the photosensitivity. Moreover, an adjacent photosensitive device in an array-shaped photo-gating switch system to be described later may also be affected to a certain extent. The photosensitive device shown in FIGS. 7a and 7b is introduced to resolve the problems.

In the photo-gating switch system 10 shown in FIGS. 7a and 7b, the rear surface of the substrate 1 is partially etched to selectively form the groove 16 either before or after forming the MIT device 7. The depth of the groove 16 may be equal to or smaller than the thickness of the substrate 1 as shown in FIG. 7.

In other words, the substrate 1 in the photosensitive region 13 is formed to have a thickness smaller than the thickness of the substrate 1 in the remaining regions by selectively forming the groove 16 in the rear surface of the substrate 1. The substrate 1 may be formed to have a thickness thicker than zero or may be completely removed in the photosensitive region 3. As shown in FIG. 7a, if the substrate 1 in the photosensitive region 3, that is, if the rear of the photosensitive region 3, is exposed, a non-transparent substrate can be used as the substrate 1.

In the photo-gating switch system 10 shown in FIGS. 7a and 7b, the substrate 1 has a small thickness inside the groove correspond to the photosensitive region 13, where the light 11 goes through the transparent region 17. As a result, the light 11 is focused to the photosensitive region 13, so that the photo-gating switch system 10 has higher sensitivity.

In the photo-gating switch system 10 shown in FIGS. 7a and 7b, the reflectance of light varies according to the inward angle of the side surface of the groove 16. At an angle at which the total reflection occurs in the groove, the light is reflected from the surface of the groove. When the light is reflected from sidewall of groove of the substrate 1, the reflected light can be focused to the photosensitive region 13. To totally reflect the light from the surface, the incident angle of light with respect to the sidewall surface of the groove 16, or the incident angle of light with respect to a vertical line (a line perpendicular to the surface of substrate), should be greater than a Brewster angle.

The Brewster angle may be expressed using the arc tangent: {arctan(n2/n1)}. For example, if light enters the glass from air, n1 is approximately 1.0, which is the refractivity of air, while n2 is approximately 1.5, where n is the refractive index. In this case, the Brewster angle of the visible rays is approximately 56 degrees. This angle is the incident angle of light from the light source 15 with respect to the side surface of the groove 16′. The appropriate inward angle of the sidewall surface of the groove 16 varies according to the type of the light source 15.

Although the appropriate inward angle of the sidewall surface of the groove 16 varies according to the type of the light source 15, it is more efficient if the angle of the sidewall surface of the groove 16 to the photosensitive layer is larger than 45 and smaller than 90 degrees.

Since the light source 15 may be either a planar light source or a point light source, it may be more efficient if the angle of the sidewall surface of the groove 16 to the photosensitive layer is greater than 45 degrees in consideration of both types of the light source. Moreover, the sidewall surface of the groove 16 may be coated with a thin film with high reflectance to deliver the light 11 to the photosensitive region 13 with higher intensity by focusing the light 11 via the sidewall surface of the groove 16 in the photo gating switch system 10 shown in FIGS. 7a and 7b.

Also, the photo-gating switch system 10 shown in FIGS. 7a and 7b is easy to manufacture and the durability of the substrate 1 is not deteriorated since only a limited section of the substrate 1 is etched. Since the photo-gating switch system 10 shown in FIGS. 7a and 7b may have high photo-transmittance at a required region by etching a limited section of the substrate 1 and forming the grooves, any substrates may be used as the substrate 1 regardless of the initial thickness of the substrate or its photo-transmittance.

Referring to FIGS. 8 and 9, FIG. 8 shows a case where the bottom surface of the groove 16 is tetragonal, while FIG. 9 shows a case where the bottom surface of the groove 16 is circular. The groove 16 may have either tetragonal or circular shape, and may also have other shapes such as hexagonal or octagonal shape. The inner space of the groove 16 is the photo-transparent region 17 and the size may be corresponded to the size of photosensitive region 3.

As described hereinbefore, since the groove 16 both lowers diffusion of light and focuses the light to the transparent region 17 or the photosensitive region 3, the photosensitivity of the photo-gating switch system 10 shown in FIGS. 7a and 7b is further improved. The depth of the groove 16 should be equal to or smaller than the thickness of the substrate 1. If the groove 16 is formed before forming the MIT device, the substrate 1 may have any thickness as long as the thickness does not affect the forming of the MIT device.

The light source 15 used in either the photo-gating switch system 10 or an array-shaped photo gating switch system 30 according to another embodiment of the present invention may be any device that emits light (electromagnetic waves) in principle. The light source 15 emits light with a wavelength in one of the ultraviolet region, visible ray region, or infrared region. Since the light emitted by the light source 15 should be sensitively absorbed by the photosensitive device, the light wavelength is decided according to the element or the compound forming the photosensitive device.

The light source 15 may be one of an electroluminescence display (ELD), a light emitting diode (LED), an organic light emitting diode (OLED), a laser diode (LD), a plasma display panel (PDP), a liquid crystal display (LCD) including a backlight unit, a field emission display (FED), a fluorescent lamp, a light bulb, and a laser. Of these light sources, ELD, OLED, PDP, LCD, and FED are array-shaped light sources, and may be used in the array-shaped photosensitive device as described later.

Various light-emission mechanisms such as electroluminescence (EL) by applying an electric field to a luminescent substance, photoluminescence (PL) of longer wavelength by applying ultraviolet light, blue light, green light, etc., to a fluorescent substance, cathode-luminescence (CL) by colliding electrons having high energy, and other type of EL by recombining electrons and holes, which is the basic principle of a LED, have been known. In most cases, the light source 15 may use any one of the light-emitting mechanisms.

In FIGS. 6 through 9, a unitary photo-gating switch system 10 is configured with a singular light source. However, the array-shaped photo-gating switch system 30 may be configured by connecting an array module for the array-shaped light source 15 and a photosensitive device array having dimensions corresponding to the array module. The photosensitive device may be an MIT device array.

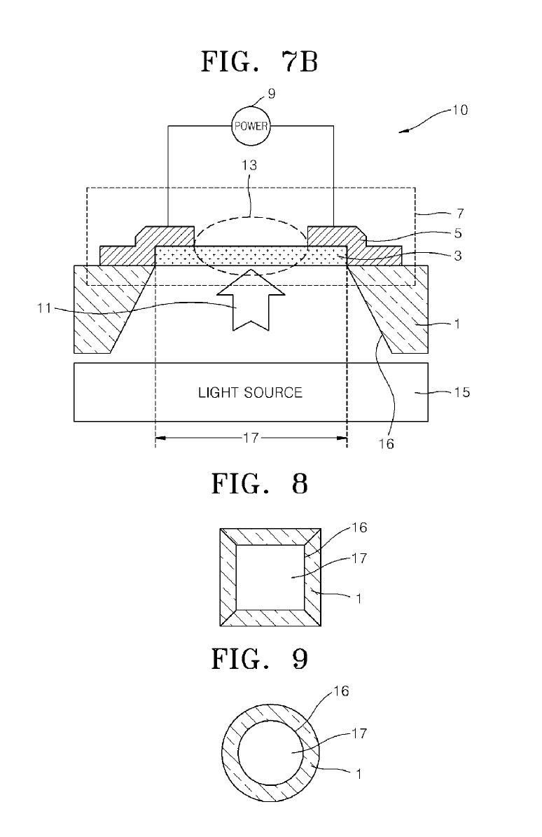

FIG. 10 is a plan view of a light source array usable in the array-shaped photo-gating switch system according to an embodiment of the present invention.

More particularly, a light source array module 21 may be a passive matrix type module or an active matrix type module. The passive matrix type module has pixels, namely, unitary light sources, positioned in a matrix shape at the intersections of columns and rows. The active matrix type module includes a thin-film transistor (TFT) in each of the pixels, namely, the light sources, and operates each of the pixels independently. The array-shaped photo-gating switch system 30 according to an embodiment of the present invention may use both the passive or active matrix type light source array modules.

In FIG. 10, the light source array module 21 is a passive matrix type module. As shown in FIG. 10, if a column i and a row line j are selected, a pixel 19, namely a unitary light source, at i and j coordinates is turned on to emit light. Each of the pixels may be turned on selectively by a data line, and all of the pixels may be turned on simultaneously if necessary.

Meanwhile, any type of light source may be included in the light source array module 21 as described hereinbefore. Also, the light source array module 21 may be integrated with the photosensitive device array 20 as described later. The flat panel display type light source such as the ELD, the OLED, the PDP, the FED, or the LCD including a backlight unit may be integrated as the light source together with the photosensitive device array 20, and a surface-emitting LD or a surface-emitting LED may also be used as the light sources.

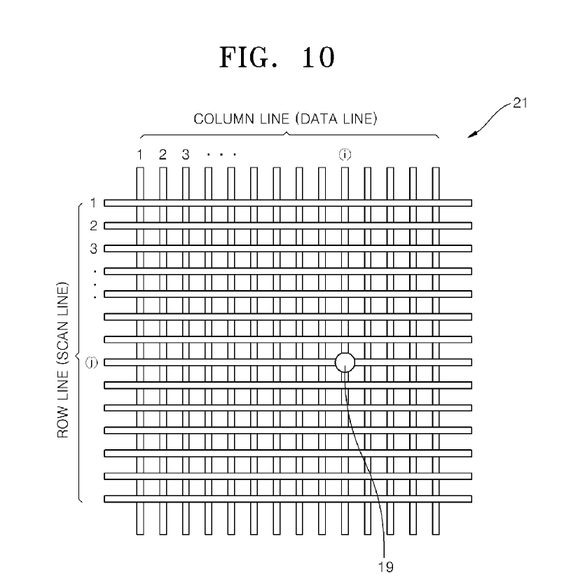

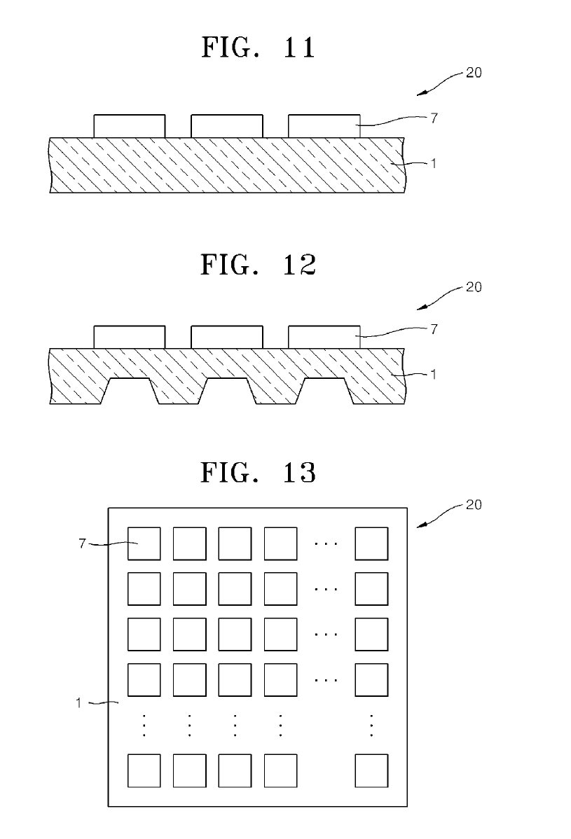

FIGS. 11 and 12 are sectional views of an array-shaped photo-gating switch system according to the present invention, and FIG. 13 is a plan view of the photosensitive device array shown in FIGS. 11 and 12.

More particularly, FIG. 11 is a cross-sectional view of a photosensitive device array 20, in which unitary photosensitive devices 7 are regularly formed in an array shape on a substrate 1. To have higher photo-transmittance, the substrate 1 may be thinned to have a thickness of a few tens of μm.

FIG. 12 shows the photosensitive device array 20 in which a groove 16 is selectively formed in the rear surface of the substrate 1 and the unitary photosensitive devices 7 are formed in an array shape on the substrate 1.

When the groove 16 is formed, the substrate 1 may or may not remain in the photosensitive region. If the substrate 1 remains in the photosensitive region, the thickness of the substrate 1 may be smaller than the widths of the intervals between the unitary photosensitive devices 7.

In FIGS. 11 and 12, a distributor (not shown) may be employed for light from the singular light source to be irradiated with laterally uniform intensity to the photosensitive device array 20 including the unitary photosensitive devices 7.

In FIGS. 11 and 12, the unitary photosensitive devices may be unitary MIT devices, while the photosensitive device array may be an MIT device array.

FIG. 13 is a plan view of the photosensitive device array shown in FIGS. 11 and 12, showing the photosensitive device array 20 in which the unitary photosensitive devices 7 are regularly formed in a matrix shape on the substrate 1. The unitary photosensitive device 7 is described in detail with reference to FIGS. 6 and 7.

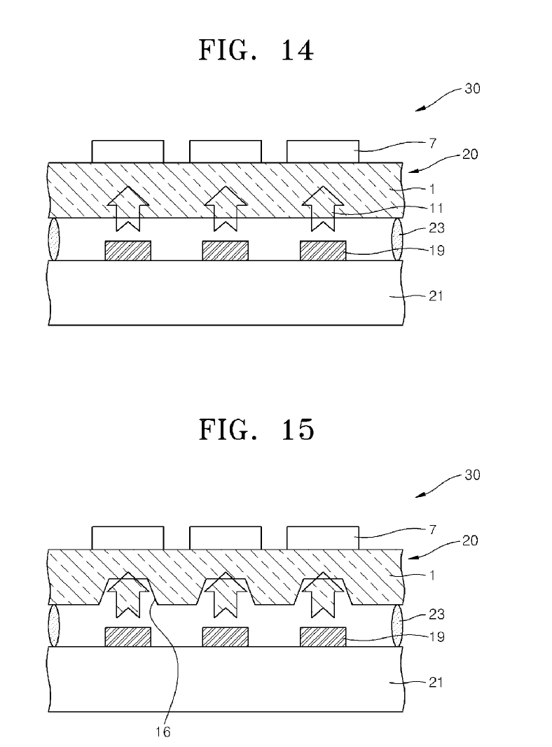

FIGS. 14 and 15 are cross-sectional views of array-type photo-gating switch systems in each of which a photosensitive device array and a light source array module are integrated according to another embodiment of the present invention.

More particularly, an array-shaped photo-gating switch system 30 is configured by integrating a photosensitive device array 20 and a light source array module 21. The array-type photo-gating switch system 30 of FIG. 14 is a combination of FIGS. 10 and 11, including the photosensitive device array 20 formed on a substrate 1 and the light source array module 21.

FIG. 15 is a combination of FIGS. 10 and 12, in which the photosensitive device array 20 formed on a substrate 1 on which grooves are formed and the light source array module 21 are integrated. In FIGS. 14 and 15, reference number 23 represents a sealant. The unitary photosensitive device 7 is described in detail with reference to FIGS. 6 and 7.

Commonly, a cover glass is often used for protection when a planar light source is packaged. Using the cover glass may be essential in some cases. Meanwhile, the light source array module 21 may not include a separate cover glass since it may use the substrate 1 on which photosensitive devices are formed as the cover glass.

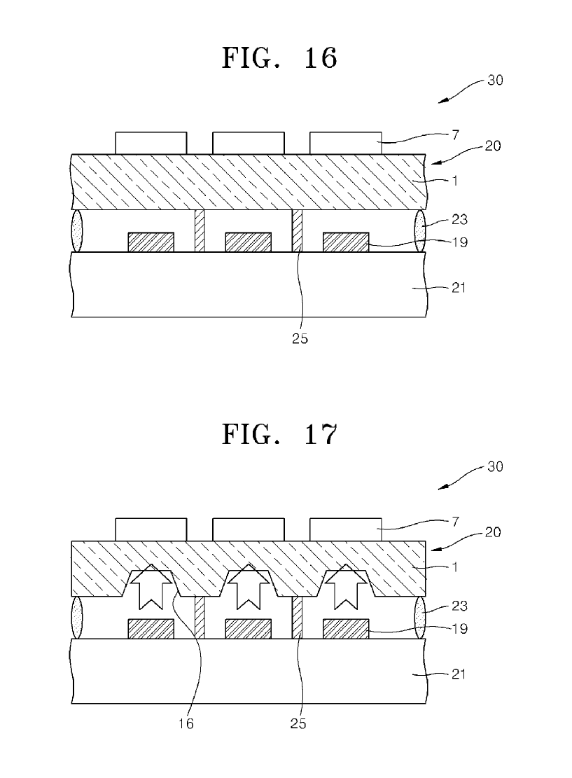

FIGS. 16 and 17 are cross-sectional views of array-type photo-gating switch systems including partition walls according to another embodiment of the present invention.

More particularly, FIGS. 16 and 17 show array-type photo gating switch systems 30 shown in FIGS. 14 and 15, further including the partition walls. As also shown in FIGS. 16 and 17, partition walls 25 are introduced between the unitary light sources and on the light source array module 21 at both ends of the groove. The partition walls 25 prevent light emitted by each of the unitary pixels 19 from affecting unitary photosensitive devices 7 adjacent to the unitary photosensitive device 7 where light is emitted to, and thus only light traveling in a straight line may be used by the unitary photosensitive device 7.

If the groove 16 is formed in the substrate 1 as shown in FIG. 17, the effect of light emitted by each of the unitary pixels 19 to the neighboring unitary photosensitive device 7 may be prevented without introducing the partition walls 25. The unitary photosensitive device 7 is described in detail with reference to FIGS. 6 and 7.

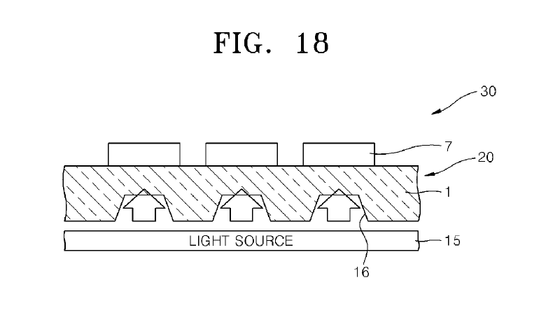

FIG. 18 is a view of a photo-gating switch system in which a unitary light source is capable of turning on/off array-type photosensitive devices simultaneously according to another embodiment of the present invention.

More particularly, an array-type photo-gating switch system 30 includes a photosensitive device array 20 having a plurality of unitary photosensitive devices 7 formed in an array type on a photo-transmissive substrate 1 in which a groove 16 is formed. While FIG. 18 shows the transparent substrate 1 in which the groove 16 is formed, the groove 16 may not be necessary as described hereinbefore. Also, a light source 15 emitting light 11 is disposed beneath the photosensitive device array 20 including the transparent substrate 1 on which the unitary photosensitive devices are formed. Accordingly, the light 11 emitted from the light source 15 is capable of turning on/off the array-shaped photosensitive devices 7 simultaneously.

The array-type photo-gating switch system 30 shown in FIG. 18 has no restriction on the type of the light source 15. Thus, the light source 15 may be a laser source, a fluorescent lamp, an incandescent bulb, etc. The fluorescent lamp may be a cold cathode fluorescent lamp (CCFL), which is small and has very high brightness due to recent developments of display technology.

While the present invention has been particularly shown and described with reference to exemplary embodiments thereof, it will be understood by those of ordinary skill in the art that various changes in form and details may be made therein without departing from the spirit and scope of the present invention as defined by the following claims.

### INDUSTRIAL APPLICABILITY

The present invention relates to a photo-gating switch system with fast on/off switching and excellent photosensitivity. The present invention also relates to a photo-gating switch system in which a light source and a photosensitive device such as photo-detector or photo-switches may be easily integrated.

1. A photo-gating switch system comprising:
a photosensitive device formed on a substrate; and
a light source located beneath the substrate and irradiating light to the photosensitive device.

2. The photo-gating switch system of claim 1, wherein the photosensitive device comprises a photosensitive layer formed on the substrate and electrodes formed at both ends of the photosensitive layer.

3. The photo-gating switch system of claim 1, wherein the photosensitive device comprises a photosensitive layer having a photosensitive region to which light is irradiated from the light source, and a groove is selectively formed on a rear surface of the substrate in a region of the substrate corresponding to the photosensitive region so that a thickness of the substrate in the region corresponding to the photosensitive region is smaller than a thickness of the substrate in remaining regions.

4. The photo-gating switch system of claim 1, wherein the thickness of the substrate in the region corresponding to the photosensitive region is greater than or equal to zero.

5. The photo-gating switch system of claim 1, wherein the photosensitive device is an MIT (metal-insulator transition) device on which the MIT occurs when light (electromagnetic waves) or both light and an electric field are applied thereto.

6. A photo-gating switch system comprising:
an MIT device formed on a substrate, whereon the MIT occurs on the MIT device when light (electromagnetic waves) or both light and an electric field are applied thereto;
a light source located beneath the substrate and irradiating light toward the MIT device, and the light reaches the MIT device.

7. The photo-gating switch system of claim 6, wherein the MIT device comprises:
an MIT layer formed on the substrate; and
electrodes formed at both ends of the MIT layer.

8. A photo-gating switch system comprising:
a photosensitive device array including a plurality of unitary photosensitive devices formed in an array shape on a substrate; and
a light source located beneath the substrate.

9. The photo-gating switch system of claim 8, wherein each of the unitary photosensitive devices comprises:
a photosensitive layer formed on the substrate; and
electrodes formed at both ends of the photosensitive layer.

10. The photo-gating switch system of claim 8, wherein the unitary photosensitive device comprises a photosensitive layer including a photosensitive region to which light is irradiated from the unitary light source, and a groove is selectively formed in a rear surface of the substrate so that a thickness of the substrate in a region corresponding to the photosensitive region is smaller than the remaining region.

11. The photo-gating switch system of claim 10, wherein the thickness of the substrate in the region corresponding to the photosensitive region where the groove is formed is greater than or equal to zero, and is smaller than the widths of intervals between the unitary photosensitive devices.

12. The photo-gating switch system of claim 10, wherein the light source is a light source array module in which unitary light sources, respectively irradiating light in correspondence with the unitary photosensitive devices, are formed, and partition walls are introduced between the unitary light sources and on the light source array module at both ends of the groove.

13. The photo-gating switch system of claim 8, wherein the unitary photosensitive device is an MIT device on which the MIT occurs when light or both light and an electric field are applied thereto.

14. The photo-gating switch system of claim 8, wherein the light source is a light source array module wherein unitary light sources, respectively irradiating light in correspondence with the unitary photosensitive devices, are formed.

15. The photo-gating switch system of claim 14, wherein partition walls are introduced to partition the unitary light sources on the light source array module.

16. The photo-gating switch system of claim 14, wherein the light source array module is one of an ELD (electroluminescence display), a LED (light emitting diode), an OLED (organic light emitting diode), an LD (laser diode), a PDP (plasma display panel), an LCD (liquid crystal display) comprising a backlight unit, and a FED (field emission display).

17. A photo-gating switch system, comprising:
an MIT device array formed on a substrate in an array shape and having a plurality of unitary MIT devices on which the MIT occurs when light or both light and an electric field are applied to the unitary MIT devices; and
a light source located beneath the substrate.

18. The photo-gating switch system of claim 17, wherein the MIT device comprises:
an MIT layer formed on the substrate; and
electrodes formed at both ends of the MIT layer.

19. The photo-gating switch system of claim 17, wherein the MIT device comprises a photosensitive layer having a photosensitive region to which light is irradiated from the unitary light source, and a groove is selectively formed from a rear surface of the substrate in a region corresponding to the photosensitive region so that a thickness of the substrate in the region corresponding to the photosensitive region is smaller than a thickness of the substrate in other regions.

20. The photo-gating switch system of claim 19, wherein the thickness of the substrate in the region corresponding to the photosensitive region is greater than or equal to zero, and is smaller than width of intervals between the photosensitive devices.

21. The photo-gating switch system of claim 20, wherein the light source is a light source array module wherein unitary light sources, respectively irradiating light in correspondence with the unitary photosensitive devices, are formed.

22. The photo-gating switch system of claim 17, wherein the light source array module is one of an ELD (electroluminescence display), a LED (light emitting diode), an OLED (organic light emitting diode), an LD (laser diode), a PDP (plasma display panel), an LCD (liquid crystal display) including a backlight unit, and a FED (field emission display).

23. A photo-gating switch system, comprising:
a photosensitive device array formed on a light-transparent substrate in an array shape and having a plurality of unitary photo-detecting devices; and
a light source located beneath t the photo-transmissive substrate.
